(19) United States
(12) Patent Application Publication
(10) Pub. No.: US 2025/0098487 A1
(43) Pub. Date: Mar. 20, 2025

(54) Display Device

(71) Applicant: LG Display Co., Ltd., Seoul (KR)

(72) Inventor: Yuseok Jung, Seoul (KR)

(21) Appl. No.: 18/767,875

(22) Filed: Jul. 9, 2024

(30) Foreign Application Priority Data
Sep. 18, 2023 (KR) 10-2023-0123962

(51) Int. Cl. H10K 59/80; H10K 59/122

(52) U.S. Cl. CPC H10K 59/873; H10K 59/122

(57) ABSTRACT

A display device includes a substrate including an active area and a non-active area which extends from the active area, a light emitting diode which is disposed on the substrate and includes an anode, a light emitting layer, and a cathode, a dam disposed on the substrate in the non-active area and a step relief pattern disposed in a part of a surface of the dam. The dam includes a first insulating layer and a second insulating layer on the first insulating layer, and the step relief pattern is disposed to enclose a side surface of the first insulating layer and a lower portion of a side surface of the second insulating layer.

### CROSS-REFERENCE TO RELATED APPLICATION

This application claims the priority to and benefit of Republic of Korea Patent Application No. 10-2023-0123962 filed on Sep. 18, 2023, which is hereby incorporated by reference in its entirety.

### BACKGROUND

### Technical Field

The present disclosure relates to a display device, and more particularly, to a display device which relives a step of a dam to minimize or reduce permeation of oxygen and moisture through a seam of an inorganic encapsulation layer.

### Description of the Related Art

An applicable range of the liquid crystal display (LCD) device and the organic light emitting display (OLED) device which have been widely used until now is gradually expanded.

Unlike a liquid crystal display (LCD) device which includes a backlight, an organic light emitting display (OLED) device does not require a separate light source. Therefore, the organic light emitting display device can be manufactured to be light and thin and has a process advantage and has a low power consumption in accordance with the low voltage driving. First of all, the organic light emitting display device includes a self-emitting element and includes layers formed of organic thin films so that the flexibility and elasticity are superior to the other display devices.

### SUMMARY

The inventors have recognized that a seam and a crack may be generated in an inorganic encapsulation layer due to a step of a dam surface. Accordingly, an object to be achieved by the present disclosure is to provide a display device which relieves a step of a dam surface to minimize or reduce generation of a seam and a crack of an inorganic encapsulation layer.

Another object to be achieved by the present disclosure is to provide a display device which suppresses permeation of moisture through a seam and a crack of an inorganic encapsulation layer.

Still another objective to be achieved by the present disclosure is to provide a display device which suppresses hydrogen diffusion to a transistor.

Still another objective to be achieved by the present disclosure is to provide a display device with improved reliability and display quality.

Objects of the present disclosure are not limited to the above-mentioned objects, and other objects, which are not mentioned above, can be clearly understood by those skilled in the art from the following descriptions.

According to an aspect of the present disclosure, a display device includes a substrate including an active area and a non-active area which encloses the active area, a light emitting diode which is disposed on the substrate and includes an anode, a light emitting layer, and a cathode, a dam disposed on the substrate in the non-active area and a step relief pattern which is disposed in a part of a surface of the dam. The dam includes a first insulating layer and a second insulating layer on the first insulating layer, and the step relief pattern is disposed so as to enclose a side surface of the first insulating layer and a lower portion of a side surface of the second insulating layer. Accordingly, the step of the dam surface is relieved to minimize or reduce generation of the seam and the crack of the encapsulation layer and suppress inflow of foreign particles through the seam and the crack of the encapsulation layer, thereby improving reliability and improving a display quality.

Other detailed matters of the exemplary embodiments are included in the detailed description and the drawings.

According to the exemplary embodiment of the present disclosure, a step of a dam surface is relieved to minimize or reduce generation of a seam and a crack.

According to the exemplary embodiment of the present disclosure, the crack generated in the encapsulation layer due to a step of a dam surface may be suppressed.

According to the exemplary embodiment of the present disclosure, the degradation of the characteristic of the transistor due to hydrogen may be suppressed.

According to the exemplary embodiment of the present disclosure, the reliability and the display quality may be improved.

The effects of the present disclosure are not limited to the aforementioned effects, and other effects, which are not mentioned above, will be apparently understood by a person having ordinary skill in the art from the following description.

Other detailed matters of the exemplary embodiments are included in the detailed description and the drawings.

### BRIEF DESCRIPTION OF DRAWINGS

The above and other aspects, features and other advantages of the present disclosure will be more clearly understood from the following detailed description taken in conjunction with the accompanying drawings.

FIG. 1 is a schematic diagram of a display device according to an exemplary embodiment of the present disclosure.

FIG. 2 is a cross-sectional view taken along line II-II′ of FIG. 1 according to an exemplary embodiment of the present disclosure.

FIG. 3 is a cross-sectional view taken along line III-III′ of FIG. 1 according to an exemplary embodiment of the present disclosure.

FIG. 4 is a cross-sectional view of a display device according to another exemplary embodiment of the present disclosure.

FIG. 5 is a cross-sectional view of a display device according to still another exemplary embodiment of the present disclosure.

FIG. 6 is a cross-sectional view of a display device according to still another exemplary embodiment of the present disclosure.

FIG. 7 is a cross-sectional view of a display device according to still another exemplary embodiment of the present disclosure.

FIG. 8 is a cross-sectional view of a display device according to still another exemplary embodiment of the present disclosure.

FIG. 9 is a cross-sectional view of a display device according to still another exemplary embodiment of the present disclosure.

FIG. 10 is a cross-sectional view of a display device according to still another exemplary embodiment of the present disclosure.

FIG. 11 is a cross-sectional view of a display device according to still another exemplary embodiment of the present disclosure.

FIG. 12 is a cross-sectional view of a display device according to still another exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, areas, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “include,” “have,” “comprise,” “contain,” “constitute,” “make up of,” and “formed of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “over”, “below”, “under”, “beside”, “beneath”, “near”, “close to,” “adjacent to”, “on a side of”, “next”, one or more parts may be positioned between the two parts unless the terms are used with the term “immediately” or “directly”.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

In describing temporal relationship, terms such as “after,” “subsequent to,” “following,” “next,” “before,” and the like may include cases where any two events are not consecutive, unless the term such as “immediately” “just” or “directly” is explicitly used.

When an element or layer is disposed “on” another element or layer, another layer or another element may be interposed directly on the other element or therebetween.

Although the terms “first”, “second”, “A”, “B”, “(a)”, “(b)”, and the like are used for describing various components, these components are not confined by these terms. These terms are merely used for distinguishing one component from the other components. Therefore, a first component to be mentioned below may be a second component in a technical concept of the present disclosure.

In addition, terms, such as first, second, A, B, (a), (b), or the like may be used herein when describing components of the present disclosure. Each of these terminologies is not used to define an essence, order, or sequence of a corresponding component but used merely to distinguish the corresponding component from other components. In the case that it is described that a certain structural element or layer is “connected”, “coupled”, “adhered” or “joined” to another structural element or layer, it is typically interpreted that another structural element or layer may be “connected”, “coupled”, “adhered” or “joined” to the structural element or layer directly or indirectly.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

A term “device” used herein may refer to a display device including a display panel and a driver for driving the display panel. Examples of the display device may include a light emitting device, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including the light emitting device and the like, but embodiments of the present disclosure are not limited thereto.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, a display device according to exemplary embodiments of the present disclosure will be described in detail with reference to accompanying drawings.

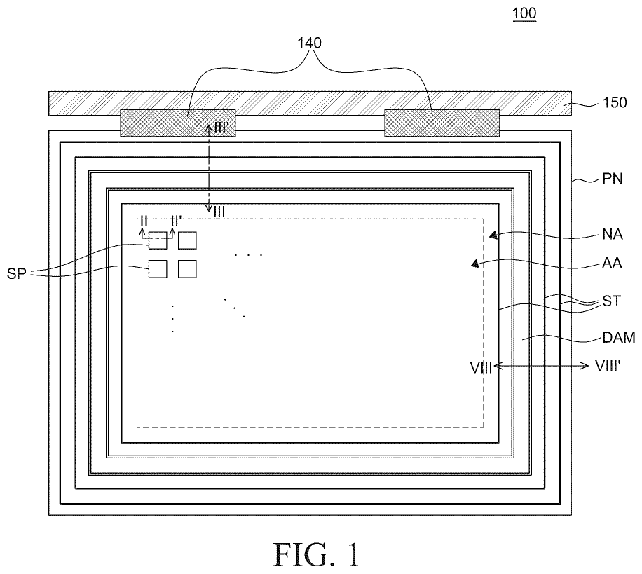

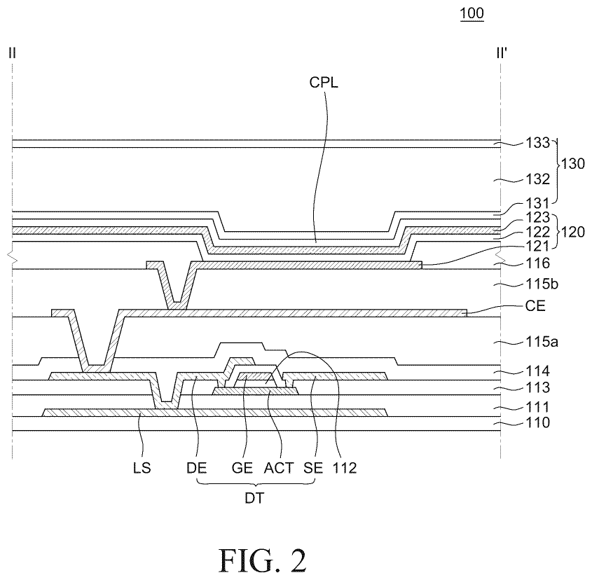

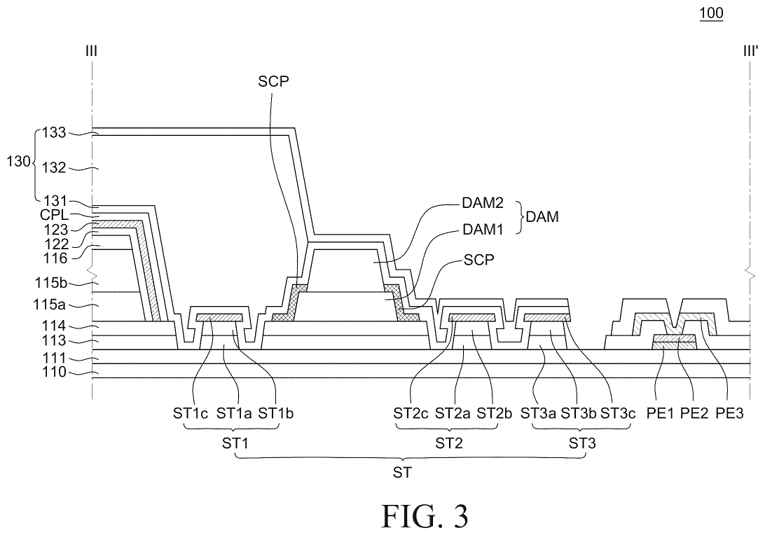

FIG. 1 is a schematic diagram of a display device according to an exemplary embodiment of the present disclosure. FIG. 2 is a cross-sectional view taken along line II-II′ of FIG. 1 according to an exemplary embodiment of the present disclosure. FIG. 3 is a cross-sectional view taken along line III-III′ of FIG. 1 according to an exemplary embodiment of the present disclosure. For the convenience of description, in FIG. 1, among various components of the display device 100, only a display panel PN, a flexible film 140, and a printed circuit board 150 are illustrated, but components of the display device 100 of the present disclosure are not limited thereto. Meanwhile, all the components of each display device according to all embodiments of the present disclosure are operatively coupled and configured.

Referring to FIG. 1, the display device 100 may include a display panel PN including a plurality of sub pixels SP, a flexible film 140, and a printed circuit board 150.

The display panel PN is a configuration which displays images to the user and may include the plurality of sub pixels SP. In the display panel PN, an active area AA and a non-active area NA disposed in the vicinity of the active area AA, surrounding the active area AA, or around the active area AA may be defined.

The active area AA is an area in which images are displayed in the display device 100. In the active area AA, a plurality of pixel regions may be arranged in a matrix form along a plurality of row and column lines. The plurality of pixel regions may include pixel regions displaying different colors, for example, red (R), green (G), and blue (B), or red (R), green (G), blue (B), and white (W). At this time, the red (R), green (G), and blue (B) pixel regions that are adjacent to each other or the red (R), green (G), blue (B), and white (W) pixel regions that are adjacent to each other may function as a unit pixel for displaying a color image.

In the active area AA, a plurality of sub pixels SP which configures the plurality of pixels and a circuit for driving the plurality of sub pixels may be disposed. The plurality of sub pixels SP is a minimum unit which configures the active area AA and n sub pixels SP may form one pixel. Each of the plurality of sub pixels SP may emit light having different wavelengths from each other. The plurality of sub pixels may include first to third sub pixels which emit different color light from each other. For example, the plurality of sub pixels SP may include a red sub pixel SPR which is a first sub pixel, a green sub pixel SPG which is a second sub pixel, and a blue sub pixel SPB which is a third sub pixel. Further, the plurality of sub pixels SP may also further include a white sub pixel.

For example, the plurality of sub pixels SP may include red, green, and blue sub-pixels, in which the red, green, and blue sub-pixels may be disposed in a repeated manner. Alternatively, the plurality of sub pixels SP may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the example embodiment of the present disclosure, the color type, disposition type, and disposition order of the sub-pixels are not limiting, and may be configured in various forms according to light-emitting characteristics, device lifespans, and device specifications.

Meanwhile, the sub-pixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each have a different light-emitting area.

In each of the plurality of sub pixels SP, a light emitting diode and a thin film transistor for driving the light emitting diode may be disposed. The plurality of light emitting diodes may be defined in different manners depending on the type of the display panel. For example, when the display panel PN is an inorganic light emitting display panel, the light emitting element may be an inorganic light emitting diode (LED) or a micro light emitting diode (micro LED), and when the display panel is an organic light emitting display panel, the light emitting diode may be an organic light emitting diode (OLED), and embodiments of the present disclosure are not limited thereto.

A plurality of lines through which various signals are transmitted to the plurality of sub-pixels SP are disposed in the active area AA. For example, the plurality of lines may include the plurality of data lines DL through which the data voltages are supplied to each of the plurality of sub-pixels SP, the plurality of scan lines SL through which the scan signal is supplied to each of the plurality of sub-pixels SP, and the like. The plurality of scan lines SL may extend in one direction in the active area AA and may be connected to the plurality of sub-pixels SP, and the plurality of data lines DL may extend in a direction which differs from the one direction in the display area AA and may be connected to the plurality of sub-pixels SP. In addition, although the low potential power supply line, the high potential power supply line, and the like may be further disposed in the active area AA, the present disclosure is not limited thereto.

The non-active area NA is an area where images are not displayed so that the non-active area NA may be defined as an area extending from the active area AA. In the non-active area NA, a link line, a pad electrode, driving ICs, such as a gate driver IC and a data driver IC, or the like for transmitting a signal to a sub pixel SP of the active area AA may be provided.

A plurality of flexible films 140 may be disposed at one end of the display device 100. The plurality of flexible films 140 is films in which various components are disposed on a base film having malleability to supply a signal to the plurality of sub pixels SP of the active area AA. The plurality of flexible films 140 is disposed in one ends of the non-active area NA of the display device 100 to supply a data voltage, etc. to the plurality of sub pixels SP of the active area AA.

In the plurality of flexible films 140, a driver such as a gate driver or a data driver may be disposed. The driver may be disposed by a chip on glass (COG), a chip on film (COF), or a tape carrier package (TCP) technique depending on a mounting method, but is not limited thereto. In the meantime, shapes and the number of the plurality of flexible films 140 illustrated in FIG. 1 are illustrative and the shapes and the number of the flexible films 140 may be changed in various forms depending on the necessity, but are not limited thereto.

The printed circuit board 150 may be connected to the plurality of flexible films 140. The printed circuit board 150 is a component which supplies signals to the driving IC. Various components may be disposed in the printed circuit board 150 to supply various driving signals such as a driving signal or a data voltage to the driving IC.

Referring to FIGS. 1 and 2, the display panel PN may include a substrate 110. The substrate 110 is a support member for supporting other components of the display device 100 and may be configured by an insulating material. For example, the substrate 110 may be formed of glass, resin, or the like. Further, the substrate 110 may be configured to include plastics such as polymer or polyimide (PI) or may be formed of a material having flexibility. In some example embodiments, the substrate 110 may be made of a flexible plastic material or flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto.

A light shielding layer LS may be disposed on the substrate 110. The light shielding layer LS blocks light which is incident to an active layer ACT of the plurality of transistors to minimize or at least reduce a leakage current. For example, the light shielding layer LS is disposed below the active layer ACT of the driving transistor DT to block light incident onto the active layer ACT. If light is irradiated onto the active layer ACT, a leakage current is generated, which deteriorates the reliability of the driving transistor DT. Accordingly, the light shielding layer LS which blocks the light is disposed on the substrate 110 to improve the reliability of the transistor DT. The light shielding layer LS may be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 may be disposed on the light shielding layer LS. The buffer layer 111 may reduce permeation of moisture or impurities through the substrate 110. For example, the buffer layer 111 may be configured by a single layer, a double layer or more layers of silicon oxide (SiOx) or silicon nitride (SiNx), but is not limited thereto. For example, the buffer layer 111 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. However, the buffer layer 111 may be omitted depending on a type of substrate 110 or a type of the driving transistor DT, but is not limited thereto.

A driving transistor DT including an active layer ACT, a gate electrode GE, a source electrode SE, and a drain electrode DE may be disposed on the buffer layer 111.

First, the active layer ACT of the driving transistor DT may be disposed on the buffer layer 111. The active layer ACT may be formed of a semiconductor material, such as an oxide semiconductor, amorphous semiconductor, or polycrystalline semiconductor, but is not limited thereto.

The oxide semiconductor material may have an excellent effect of preventing or at least reducing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

Further, even though it is not illustrated in the drawings, other transistors, such as a switching transistor, a sensing transistor, and an emission control transistor, other than the driving transistor DT, may be further disposed. The active layers of the transistors may also be formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control transistor, may be formed of the same material, or formed of different materials.

A gate insulating layer 112 may be disposed on the active layer ACT. The gate insulating layer 112 is an insulating layer which electrically insulates the active layer ACT from the gate electrode GE and may be configured by a single layer, a double layer or more layers of silicon oxide (SiOx) or silicon nitride (SiNx), but is not limited thereto. For example, the gate insulating layer 112 may be formed by an inorganic film in a single layer or in multiple layers, for example, the inorganic film in a single layer may be a silicon oxide (SiOx) film or a silicon nitride (SiNx) film, and inorganic films in multiple layers may be formed by alternately stacking one or more silicon oxide (SiOx) films, one or more silicon nitride (SiNx) films, and one or more amorphous silicon (a-Si), but the present disclosure is not limited thereto. In the meantime, even though in FIG. 2, it is illustrated that the gate insulating layer 112 is disposed only in an area which overlaps the gate electrode GE, it is not limited thereto and the gate insulating layer 112 may be disposed so as to overlap the entire substrate 110.

The gate electrode GE may be disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

An interlayer insulating layer 113 may be disposed on the gate electrode GE. In the interlayer insulating layer 113, a contact hole through which the source electrode SE and the drain electrode DE are each connected to the active layer ACT may be formed. The interlayer insulating layer 113 is an insulating layer which protects components below the interlayer insulating layer 113 and may be configured by a single layer, a double layer or more layers of silicon oxide (SiOx) or silicon nitride (SiNx), but is not limited thereto. For example, the interlayer insulating layer 113 may be formed by an inorganic film in a single layer or in multiple layers, for example, the inorganic film in a single layer may be a silicon oxide (SiOx) film or a silicon nitride (SiNx) film, and inorganic films in multiple layers may be formed by alternately stacking one or more silicon oxide (SiOx) films, one or more silicon nitride (SiNx) films, and one or more amorphous silicon (a-Si), but the present disclosure is not limited thereto.

The source electrode SE and the drain electrode DE which are electrically connected to the active layer ACT may be disposed on the interlayer insulating layer 113. The drain electrode DE may be electrically connected to the light shielding layer LS through a contact hole of the buffer layer 111 and the interlayer insulating layer 113. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

A passivation layer 114 may be disposed on the source electrode SE and the drain electrode DE. The passivation layer 114 is an insulating layer for protecting a configuration below the passivation layer 114. For example, the passivation layer 114 may be formed of an insulating inorganic material such as silicon oxide (SiOx) or silicon nitride (SiNx) or an insulating organic material, but is not limited thereto.

A first planarization layer 115a and a second planarization layer 115b may be disposed on the passivation layer 114. The first planarization layer 115a and the second planarization layer 115b may planarize an upper portion of the pixel circuit including the driving transistor DT. The first planarization layer 115a and the second planarization layer 115b may be configured by a single layer, a double layer or more layers, and for example, configured by benzocyclobutene (BCB) or an acrylic organic material, but is not limited thereto. At this time, thicknesses of the first planarization layer 115a and the second planarization layer 115b may be approximately 1.3 μm to 1.8 μm, respectively, for example, thicknesses of the first planarization layer 115a and the second planarization layer 115b may be approximately 1.5 μm, respectively, but are not limited thereto. Meanwhile, thicknesses of the first planarization layer 115a and the second planarization layer 115b may be same or different.

A connection electrode CE may be disposed between the first planarization layer 115a and the second planarization layer 115b. The connection electrode CE is disposed below the light emitting diode 120 to electrically connect the anode 121 and the drain electrode DE of the light emitting diode 120 through a contact hole of the passivation layer 114 and the first planarization layer 115a. The connection electrode CE may be formed of a material including titanium (Ti) or alloy thereof, but is not limited thereto.

The plurality of light emitting diodes 120 is disposed in each of the plurality of sub pixels SP on the second planarization layer 115b. The light emitting diode 120 is an element which emits light by a current and may include a red light emitting diode which emits red light, a green light emitting diode which emits green light, and a light emitting diode which emits blue light and may implement light with various colors including white by a combination thereof. For example, the light emitting diode 120 may be an organic light emitting diode, an inorganic light emitting diode or a micro light emitting diode, but is not limited thereto.

The light emitting diode 120 may include an anode 121, a light emitting layer 122, and a cathode 123.

The anode 121 may be disposed on the second planarization layer 115b. The anode 121 is a layer for supplying holes to the light emitting layer 122. When the display device 100 is a top emission type, the anode 121 may include a reflective layer to allow light emitted from the light emitting layer 122 to be reflected by the anode 121 to be directed upwardly, that is, directed to the cathode 123 there above. The reflective layer may be formed of an opaque conductive material having a high reflectance, such as silver (Ag), aluminum (Al), gold (Au), molybdenum (Mo), tungsten (W), chrome (Cr), or an alloy thereof, but not limited thereto. Further, the anode 121 may further include a transparent conductive layer which is disposed on the reflective layer and supplies holes to the light emitting layer 122. Therefore, the anode 121 may have a structure in which a layer formed of indium tin oxide (ITO), a layer formed of molybdenum-titanium (MoTi), and a layer formed of indium tin oxide (ITO) are laminated, but is not limited thereto. When the display device 100 is a bottom emission type, the reflective layer is omitted in the anode 121 to allow light emitted from the light emitting layer 122 to be reflected by the cathode 123 to be directed downwardly, that is, directed to the anode 121 there below and the anode 121 may be configured by the above-described transparent conductive layer.

A bank 116 may be disposed on the second planarization layer 115b and the anode 121. The bank 116 may cover an edge of the anode 121 of the light emitting diode 120 to define an emission area. That is, the bank 116 may divide the plurality of sub pixels SP. The bank 116 may be formed of an insulating material to insulate anodes 121 of adjacent sub pixels SP from each other. Further, the bank 116 may be configured by a black bank having high light absorptance to suppress color mixture between adjacent sub pixels SP. For example, the bank 116 may be formed of a polyimide resin, an acrylic resin, or a benzocyclobutene (BCB) resin, but is not limited thereto. A thickness of the bank 116 may be smaller than that of each of the first planarization layer 115a and the second planarization layer 115b, for example, the thickness of the bank 116 may be approximately 5500 Å to 6500 Å. For example, the thickness of the bank 116 may be approximately 6000 Å, but is not limited thereto.

In the meantime, even though it is not illustrated in the drawing, a spacer may be disposed on the bank 116. The spacer is a layer which maintains a predetermined distance between a deposition mask and the bank 116 to suppress damage caused by contact with the deposition mask. Like the bank 116, the spacer may be formed of a polyimide resin, an acrylic resin, or a benzocyclobutene (BCB) resin, but is not limited thereto.

The light emitting layer 122 may be disposed on the anode 121. The light emitting layer 122 is a layer in which electrons and holes are coupled to emit light and may further include a hole injection layer, a hole transport layer, an electron transport layer, and an electron injection layer, but not limited thereto.

The cathode 123 may be disposed on the light emitting layer 122. The cathode 123 is a layer which supplies electrons to the light emitting layer 122. For example, when the display device is a top emission type, the cathode 123 may be formed of a transparent conductive material such as indium tin oxide (ITO) or indium zinc oxide (IZO), but is not limited thereto. When the display device 100 is a bottom emission type, the cathode 123 may include a reflective layer to allow light emitted from the light emitting layer 122 to be reflected by the cathode 123 to be directed downwardly, that is, directed to the anode 121 there below and the anode 121 may be configured by the above-described transparent conductive layer. The reflective layer may be formed of an opaque conductive material having a high reflectance, such as silver (Ag), aluminum (Al), gold (Au), molybdenum (Mo), tungsten (W), chrome (Cr), or an alloy thereof, but is not limited thereto.

A capping layer CPL may be disposed on the cathode 123. The capping layer CPL may improve an optical characteristic of the organic light emitting diode 120. Further, the capping layer CPL may protect the cathode 123 so as not to be oxidized or deteriorated. For example, the capping layer CPL may be formed of a material such as polymer, silicon oxide (SiOx), or silicon nitride (SiNx), but is not limited thereto. However, the present disclosure is not limited thereto and the capping layer CPL may be omitted depending on the design.

The encapsulation layer 130 may be disposed on the light emitting diode 120. The encapsulation layer 130 may protect the light emitting diode 120 from moisture, oxygen, and impacts of the outside. The encapsulation layer 130 may be formed with a multi-layered structure in which an inorganic layer formed of an inorganic insulating material and an organic layer formed of an organic material are laminated. For example, the encapsulation layer 130 may be configured by at least one organic layer and at least two inorganic layers and have a multi-layered structure in which the inorganic layers and the organic layer are alternately laminated, but is not limited thereto. For example, the encapsulation layer 130 may have a triple-layered structure including a first inorganic encapsulation layer 131, an organic encapsulation layer 132, and a second inorganic encapsulation layer 133. In this case, the first inorganic encapsulation layer 131 and the second inorganic encapsulation layer 133 may be independently formed of one or more selected from silicon nitride (SiNx), silicon oxide (SiOx), aluminum oxide (AlOx), and silicon oxynitride (SiON), but are not limited thereto. In the meantime, the organic encapsulation layer 132 may be formed of one or more selected from an epoxy resin, polyimide resin, polyethylene resin, and silicon oxycarbide (SiOC), but is not limited thereto.

Meanwhile, the encapsulation layers are not limited to three layers, for example, n layers alternately stacked between an inorganic encapsulation layer and an organic encapsulation layer (where n is an integer greater than 3) may be included.

Referring to FIGS. 1 to 3, in the non-active area NA, a dam DAM may be disposed on the passivation layer 114. The dam DAM is disposed to control the overflow of the organic encapsulation layer 132 of the encapsulation layer 130. The dam DAM may be formed by a single layer or a multiple layer. The dam DAM is disposed to suppress the overflow of the organic encapsulation layer 132 so that the first inorganic encapsulation layer 131 and the second inorganic encapsulation layer 133 may be disposed to be in contact with each other on the dam DAM.

Specifically, the dam DAM may include a first insulating layer DAM1 and a second insulating layer DAM2. The first insulating layer DAM1 may be formed on the same layer as the first planarization layer 115a and may be formed of the same material as the first planarization layer 115a, but is not limited thereto. For example, the first insulating layer DAM1 may be configured by a single layer, a double layer or more layers, and for example, configured by benzocyclobutene (BCB) or an acrylic organic material, but is not limited thereto. At this time, similar to the first planarization layer 115a, a thickness of the first insulating layer DAM1 may be approximately 1.3 μm to 1.8 μm, for example, the thickness of the first insulating layer DAM1 may be approximately 1.5 μm, but is not limited thereto.

The second insulating layer DAM2 may be formed on the first insulating layer DAM1 and may be formed on the same layer as the second planarization layer 115b and may be formed of the same material as the second planarization layer 115b, but is not limited thereto. For example, the second insulating layer DAM2 may be configured by a single layer, a double layer or more layers, and for example, configured by benzocyclobutene (BCB) or an acrylic organic material, but is not limited thereto. At this time, the second insulating layer DAM2 may be disposed to expose a part of a top surface of the first insulating layer DAM1. At this time, same as the second planarization layer 115b, a thickness of the second insulating layer DAM2 may be approximately 1.3 μm to 1.8 μm, for example, the thickness of the second insulating layer DAM2 may be approximately 1.5 μm, but is not limited thereto.

A step relief pattern SCP may be disposed in a part of a surface of the dam DAM. The step relief pattern SCP relieves a step between the first insulating layer DAM1 and the second insulating layer DAM2 of the dam DAM to suppress a seam and a crack from being generated in the first inorganic encapsulation layer 131 and the second inorganic encapsulation layer 133. Specifically, the step relief pattern SCP extends from a part of a top surface of the passivation layer 114 which is not covered by the first insulating layer DAM1 to enclose a side surface of the first insulating layer DAM1 and a lower portion of a side surface of the second insulating layer DAM2. Further, the step relief pattern may be disposed so as to be in contact with a part of a top surface of the first insulating layer DAM1 exposed by the second insulating layer DAM2. At this time, an end of the step relief pattern SCP may be disposed on the same plane as an end of the first insulating layer DAM1.

The step relief pattern SCP may be formed of a conductive material different from that of the anode 121, for example. Further, in order to suppress deterioration of the characteristic of the driving transistor DT due to the diffusion of the hydrogen of the encapsulation layer 130 to the driving transistor DT, the step relief pattern SCP may include a material including titanium (Ti) or alloy thereof, for example, molybdenum-titanium (MoTi), but is not limited thereto.

In the non-active area NA, a plurality of structures ST may be disposed inside and outside of the dam DAM. The plurality of structures ST may be disposed with a closed loop shape, as illustrated in FIG. 1.

The plurality of structures ST may include a first structure ST1, a second structure ST2, and a third structure ST3, but not limited thereto.

The first structure ST1 may be disposed inside the dam DAM, that is, between the active area AA and the dam DAM. The first structure ST1 may be formed with a structure in which a first layer ST1a, a second layer ST1b, and a third layer ST1c are laminated, but is not limited thereto. The first layer ST1a is formed of the same material as the interlayer insulating layer 113, the second layer ST1b is formed on the first layer ST1a with the same material as the passivation layer 114, and the third layer ST1c is formed on the second layer ST1b with the same material as the anode 121. For example, the first layer ST1a may be configured by a single layer, a double layer or more layers of silicon oxide (SiOx) or silicon nitride (SiNx), but is not limited thereto. For example, the first layer ST1a may be formed by an inorganic film in a single layer or in multiple layers, for example, the inorganic film in a single layer may be a silicon oxide (SiOx) film or a silicon nitride (SiNx) film, and inorganic films in multiple layers may be formed by alternately stacking one or more silicon oxide (SiOx) films, one or more silicon nitride (SiNx) films, and one or more amorphous silicon (a-Si), but the present disclosure is not limited thereto.

For example, the second layer ST1b may be formed of an insulating inorganic material such as silicon oxide (SiOx) or silicon nitride (SiNx) or an insulating organic material, but is not limited thereto.

For example, when the display device 100 is a top emission type, the anode 121 may include a reflective layer to allow light emitted from the light emitting layer 122 to be reflected by the anode 121 to be directed upwardly, that is, directed to the cathode 123 there above. The reflective layer may be formed of an opaque conductive material having a high reflectance, such as silver (Ag), aluminum (Al), gold (Au), molybdenum (Mo), tungsten (W), chrome (Cr), or an alloy thereof, but not limited thereto. At this time, the third layer ST1c may be formed of an opaque conductive material having a high reflectance, such as silver (Ag), aluminum (Al), gold (Au), molybdenum (Mo), tungsten (W), chrome (Cr), or an alloy thereof, but not limited thereto. Further, the anode 121 may further include a transparent conductive layer which is disposed on the reflective layer and supplies holes to the light emitting layer 122. Therefore, the anode 121 may have a structure in which a layer formed of indium tin oxide (ITO), a layer formed of molybdenum-titanium (MoTi), and a layer formed of indium tin oxide (ITO) are laminated, but is not limited thereto. At this time, the third layer ST1c may have a structure in which a layer formed of indium tin oxide (ITO), a layer formed of molybdenum-titanium (MoTi), and a layer formed of indium tin oxide (ITO) are laminated, but is not limited thereto. When the display device 100 is a bottom emission type, the reflective layer is omitted in the anode 121 to allow light emitted from the light emitting layer 122 to be reflected by the cathode 123 to be directed downwardly, that is, directed to the anode 121 there below and the anode 121 may be configured by the above-described transparent conductive layer. At this time, the third layer ST1c may be configured by the above-described transparent conductive layer.

The second structure ST2 and the third structure ST3 may be disposed to enclose the dam DAM at the outside of the dam DAM.

The second structure ST2 may be formed with a structure in which a first layer ST2a, a second layer ST2b, and a third layer ST2c are laminated, but is not limited thereto. The first layer ST2a is formed of the same material as the interlayer insulating layer 113, the second layer ST2b is formed on the first layer ST2a with the same material as the passivation layer 114, and the third layer ST2c is formed on the second layer ST2b with the same material as the anode 121.

The third structure ST3 may be formed so as to enclose the second structure ST2 at the outermost periphery of the substrate 110. The third structure ST3 may be formed with a structure in which a first layer ST3a, a second layer ST3b, and a third layer ST3c are laminated, but is not limited thereto. The first layer ST3a is formed of the same material as the interlayer insulating layer 113 and the second layer ST3b is formed on the first layer ST3a with the same material as the passivation layer 114, and the third layer ST3c is formed on the second layer ST3b with the same material as the anode 121.

The plurality of structures ST may be formed with an under-cut shape to elongate a permeation path of moisture or oxygen from the outside of the display device 100 to delay the permeation of the moisture and oxygen. That is, an area of a bottom surface of the third layer ST1c of the first structure ST1 may be larger than an area of a top surface of the second layer ST1b of the first structure ST1. An area of a bottom surface of the third layer ST2c of the second structure ST2 may be larger than an area of a top surface of the second layer ST2b of the second structure ST2. An area of a bottom surface of the third layer ST3c of the third structure ST3 may be larger than an area of a top surface of the second layer ST3b of the third structure ST3. However, the present disclosure is not limited thereto. At this time, the first inorganic encapsulation layer 131 is disposed to enclose a surface of the plurality of structures ST and the second inorganic encapsulation layer 133 is disposed so as to enclose surfaces of the second structure ST2 and the third structure ST3. Therefore, the permeation path of moisture and oxygen from the outside of the display device 100 is elongated to delay the permeation of moisture and oxygen.

A pad electrode PAD may be disposed at the outside of the plurality of structures ST. Even though it is not illustrated in FIG. 3, as illustrated in FIG. 1, the plurality of flexible films 140 may be disposed on the pad electrode PAD. The pad electrode PAD may include a first conductive layer PE1, a second conductive layer PE2, and a third conductive layer PE3. The first conductive layer PE1 may be formed of the same material as the active layer ACT, but is not limited thereto. For example, the first conductive layer PE1 may be formed of a semiconductor material, such as an oxide semiconductor, amorphous semiconductor, or polycrystalline semiconductor, but is not limited thereto. The second conductive layer PE2 may be disposed on the first conductive layer PE1. The second conductive layer PE2 may be formed of the same material as the gate electrode GE, but is not limited thereto. For example, the second conductive layer PE2 may be configured by a conductive material, such as copper (Cu), aluminum (Al), molybdenum (Mo), nickel (Ni), titanium (Ti), chrome (Cr), or an alloy thereof, but is not limited thereto. The third conductive layer PE3 may be disposed on the second conductive layer PE2. The third conductive layer PE3 may be formed of the same material as the source electrode SE and the drain electrode DE, but is not limited thereto. For example, the third conductive layer PE3 may be configured by a conductive material, such as copper (Cu), aluminum (Al), molybdenum (Mo), nickel (Ni), titanium (Ti), chrome (Cr), or an alloy thereof, but are not limited thereto.

At this time, the first inorganic encapsulation layer 131 and the second inorganic encapsulation layer 133 disposed between the plurality of structures ST and the pad electrode PAD may be removed by the etching process. That is, the first inorganic encapsulation layer 131 and the second inorganic encapsulation layer 133 provided at the outside of the third structure ST3 may be disconnected. This is to suppress the lifting phenomenon from propagating to the active area AA even though the first inorganic encapsulation layer 131 and the second inorganic encapsulation layer 133 are lifted during a pad open process.

During the process of manufacturing the display device, foreign particles may be introduced through various paths. At this time, in order to suppress the deterioration of the light emitting diode due to the permeation of oxygen or moisture, the encapsulation layer may be disposed on the light emitting diode. Generally, the encapsulation layer is formed with a multiple structure in which an inorganic encapsulation layer formed of an inorganic insulating material and an organic encapsulation layer formed of an organic insulating material are laminated. At this time, generally, the organic encapsulation layer is applied on a substrate in a liquid state and then is subjected to the curing process to be formed. The organic encapsulation layer has fluidity before the curing process so that there may be an overflow problem over an area where an encapsulation layer is to be formed. In order to suppress the overflow of the organic encapsulation layer, a dam may be disposed in the non-active area. Generally, the dam has a double-layered structure in which a plurality of organic insulating layers is laminated. For example, the dam DAM includes a first insulating layer DAM1 and a second insulating layer DAM2. However, layers of the dam DAM are not limited thereto.

In the meantime, the inorganic encapsulation layer is formed by deposition. When there is a step on a surface on which the inorganic encapsulation layer is deposited, there is a problem in that the inorganic encapsulation layer is not uniformly deposited. Specifically, in the vicinity of the boundary with a step, a seam or a crack may be generated in the inorganic encapsulation layer. Unlike the organic encapsulation layer, the inorganic encapsulation layer is disposed beyond the dam. At this time, when a step between a plurality of organic insulating layers which configures a dam is large, a seam or a crack is generated in the inorganic encapsulation layer during a deposition process of the inorganic encapsulation layer. Further, when oxygen or moisture permeates through the seam or cracks to propagate to the light emitting layer disposed in the active area, the reliability of the display device may be degraded.

Therefore, in the display device 100 according to the exemplary embodiment of the present disclosure, the step relief pattern SCP is disposed on a surface of the dam DAM to relieve a step between the first insulating layer DAM1 and the second insulating layer DAM2 which configures the dam DAM. Therefore, a seam and a crack may be suppressed from being generated in the first inorganic encapsulation layer 131 and the second inorganic encapsulation layer 133. Accordingly, the permeation of moisture through the seam and the crack of the first inorganic encapsulation layer 131 and the second inorganic encapsulation layer 133 may be suppressed.

That is, in the display device 100 according to the exemplary embodiment of the present disclosure, the step relief pattern SCP is disposed on the surface of the dam DAM to minimize or reduce the inflow of foreign particles through the seam and the crack of the encapsulation layer 130. Therefore, the reliability may be improved and the display quality may be improved.

Further, in the display device 100 according to the exemplary embodiment of the present disclosure, a step relief pattern SCP including titanium (Ti) or the alloy thereof is disposed on the surface of the dam DAM to capture hydrogen generated in the encapsulation layer 130. Accordingly, the diffusion of the hydrogen of the encapsulation layer 130 to the driving transistor DT is suppressed to minimize or reduce degradation of the characteristic of the driving transistor DT due to the hydrogen. Further, in the display device 100 according to the exemplary embodiment of the present disclosure, a plurality of structures ST with an undercut shape are disposed at the inside and the outside of the dam DAM. For example, the plurality of structures ST may include a first structure ST1, a second structure ST2, and a third structure ST3. For example, an area of a bottom surface of the third layer ST1c of the first structure ST1 may be larger than an area of a top surface of the second layer ST1b of the first structure ST1. An area of a bottom surface of the third layer ST2c of the second structure ST2 may be larger than an area of a top surface of the second layer ST2b of the second structure ST2. An area of a bottom surface of the third layer ST3c of the third structure ST3 may be larger than an area of a top surface of the second layer ST3b of the third structure ST3. Further, the first inorganic encapsulation layer 131 and the second inorganic encapsulation layer 133 are disposed so as to enclose the surfaces of the plurality of structures ST with an undercut shape to elongate a path through which oxygen or moisture permeates. That is, the permeation of the oxygen or the moisture through the encapsulation layer 130 may be delayed.

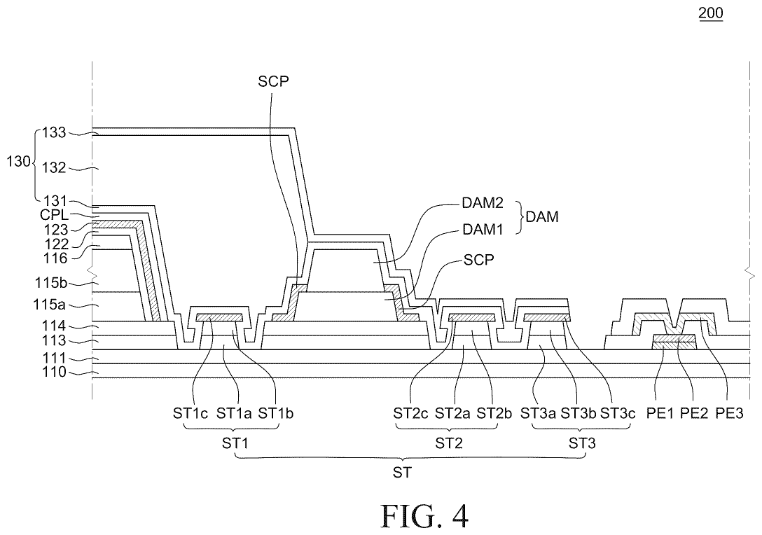

FIG. 4 is a cross-sectional view of a display device according to another exemplary embodiment of the present disclosure. The difference between a display device 200 of FIG. 4 and the display device 100 of FIGS. 1 to 3 is a step relief pattern SCP, but other components are substantially the same, so that a redundant description will be omitted.

Referring to FIG. 4, the step relief pattern SCP may be formed of the same material as the anode 121. Therefore, the step relief pattern SCP may be simultaneously formed in a deposition process of an anode 121 without adding a separate mask. Further, in order to suppress the degradation of the characteristic of the driving transistor DT due to the diffusion of the hydrogen of the encapsulation layer 130 to the driving transistor DT, the step relief pattern SCP may include a material including titanium (Ti) or alloy thereof, for example, molybdenum-titanium (MoTi), but is not limited thereto.

In the display device 200 according to another exemplary embodiment of the present disclosure, the step relief pattern SCP which is formed by a material including titanium (Ti) or alloy thereof is disposed on a surface of the dam DAM to minimize or reduce the inflow of foreign particles through the seam and the crack of the encapsulation layer 130. Therefore, the reliability may be improved and the characteristic degradation of the driving transistor DT due to the diffusion of hydrogen of the encapsulation layer 130 may be reduced.

Specifically, in the display device 200 according to another exemplary embodiment of the present disclosure, the step relief pattern SCP is simultaneously formed with the anode 121 without a separate mask-adding process so that a process efficiency may be improved and manufacturing cost may be reduced.

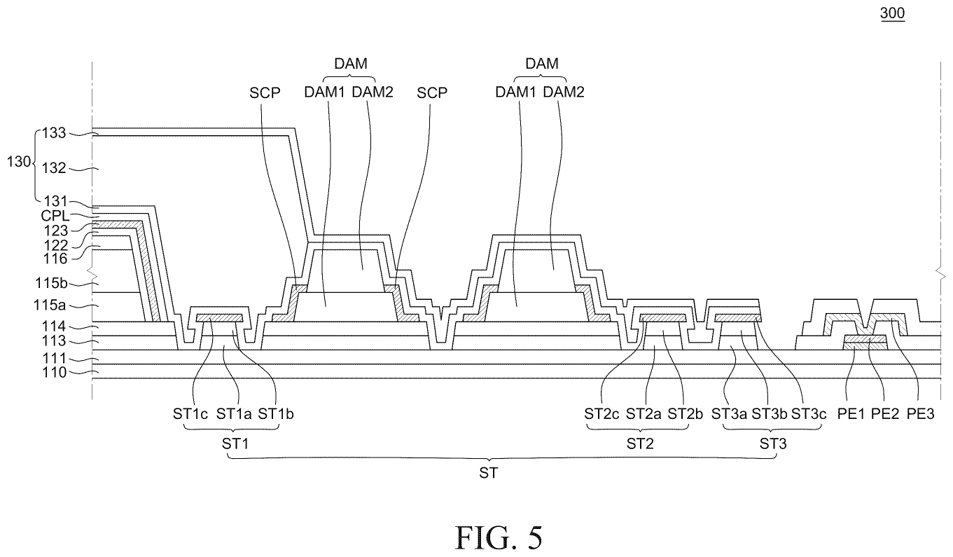

FIG. 5 is a cross-sectional view of a display device according to still another exemplary embodiment of the present disclosure. The difference between a display device 300 of FIG. 5 and the display device 200 of FIG. 4 is the number of dams DAM, but other components are substantially the same, so that a redundant description will be omitted.

Referring to FIG. 5, a plurality of dams DAM may be provided to minimize or reduce the overflow of the organic encapsulation layer 132. Even though in FIG. 5, two dams DAM are illustrated, the number of dams DAM is not limited thereto. For example, there or more dams DAM may be disposed.

Further, even though it is not illustrated in the drawing, a structure ST may be added between the plurality of dams DAM.

In the display device 300 according to still another exemplary embodiment of the present disclosure, the step relief pattern SCP which is formed by a material including titanium (Ti) or alloy thereof is disposed on a surface of the dam DAM to minimize or reduce the inflow of foreign particles through the seam and the crack of the encapsulation layer 130. Therefore, the reliability may be improved and the characteristic degradation of the driving transistor DT due to the diffusion of hydrogen of the encapsulation layer 130 may be reduced.

Specifically, in the display device 300 according to still another exemplary embodiment of the present disclosure, a plurality of dams DAM are disposed to more effectively suppress the overflow of the organic encapsulation layer 132.

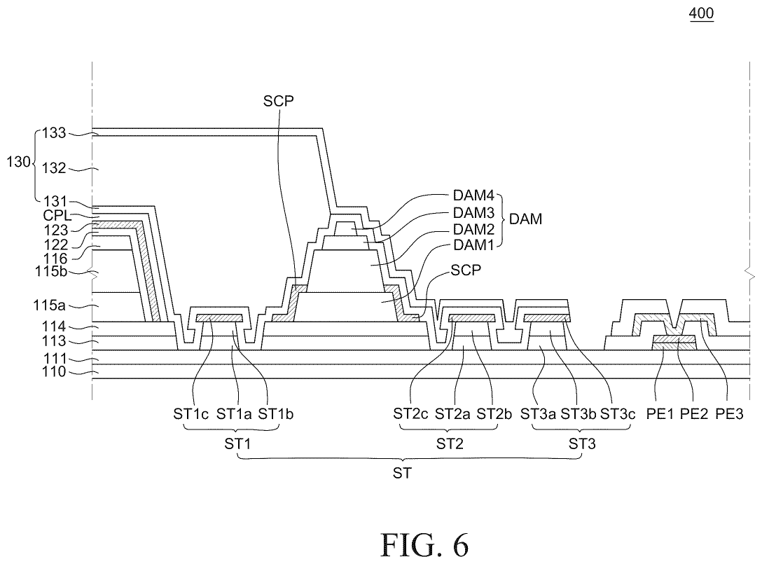

FIG. 6 is a cross-sectional view of a display device according to still another exemplary embodiment of the present disclosure. The difference between a display device 400 of FIG. 6 and the display device 200 of FIG. 4 is the presence or absence of a third insulating layer DAM3 and a fourth insulating layer DAM4, among configurations of the dam DAM, but other components are substantially the same, so that a redundant description will be omitted.

Referring to FIG. 6, the dam DAM may include a first insulating layer DAM1, a second insulating layer DAM2, a third insulating layer DAM3, and a fourth insulating layer DAM4.

The first insulating layer DAM1 may be formed on the same layer as the first planarization layer 115a and may be formed of the same material as the first planarization layer 115a, but is not limited thereto. At this time, a thickness of the first insulating layer DAM1 may be approximately 1.5 μm, but is not limited thereto.

The second insulating layer DAM2 may be disposed on the first insulating layer DAM1 and may be formed on the same layer as the second planarization layer 115b and may be formed of the same material as the second planarization layer 115b, but is not limited thereto. At this time, the second insulating layer DAM2 may be disposed to expose a part of a top surface of the first insulating layer DAM1. At this time, a thickness of the second insulating layer DAM2 may be approximately 1.5 μm, which is similar to the first insulating layer DAM1, but is not limited thereto.

The third insulating layer DAM3 may be disposed on the second insulating layer DAM2 and may be formed on the same layer as the bank 116 with the same material, but is not limited thereto. For example, the third insulating layer DAM3 may be formed of an insulating material. For example, the third insulating layer DAM3 may be formed of a polyimide resin, an acrylic resin, or a benzocyclobutene (BCB) resin, but is not limited thereto.

The fourth insulating layer DAM4 may be disposed on the third insulating layer DAM3 and may be formed on the same layer as the spacer with the same material, but is not limited thereto. For example, the fourth insulating layer DAM4 may be formed of an insulating material. For example, the fourth insulating layer DAM4 may be formed of a polyimide resin, an acrylic resin, or a benzocyclobutene (BCB) resin, but is not limited thereto.

Therefore, the third insulating layer DAM3 and the fourth insulating layer DAM4 may be thinner than the first insulating layer DAM1 and the second insulating layer DAM2, but are not limited thereto.

Further, the thickness of the third insulating layer DAM3 and the thickness of the fourth insulating layer DAM4 are smaller than the thickness of the first insulating layer DAM1 and the thickness of the second insulating layer DAM2. Therefore, a seam and a crack due to the step of the third insulating layer DAM3 and the fourth insulating layer DAM4 may not be generated in the first inorganic encapsulation layer 131 and the second inorganic encapsulation layer 133. Accordingly, a step relief pattern SCP which is in contact with side surfaces of the third insulating layer DAM3 and the fourth insulating layer DAM4 may not be necessary.

In the display device 400 according to still another exemplary embodiment of the present disclosure, the step relief pattern SCP which is formed by a material including titanium (Ti) or alloy thereof may be disposed on a surface of the dam DAM to minimize or reduce the inflow of foreign particles through the seam and the crack of the encapsulation layer 130. Therefore, the reliability may be improved and the characteristic degradation of the driving transistor DT due to the diffusion of hydrogen of the encapsulation layer 130 may be reduced.

Specifically, in the display device 400 according to still another exemplary embodiment of the present disclosure, the dam DAM may further include not only the first insulating layer DAM1 and the second insulating layer DAM2, but also the third insulating layer DAM3 and the fourth insulating layer DAM4 to be configured higher. Therefore, it is more effective to suppress the overflow of the organic encapsulation layer 130.

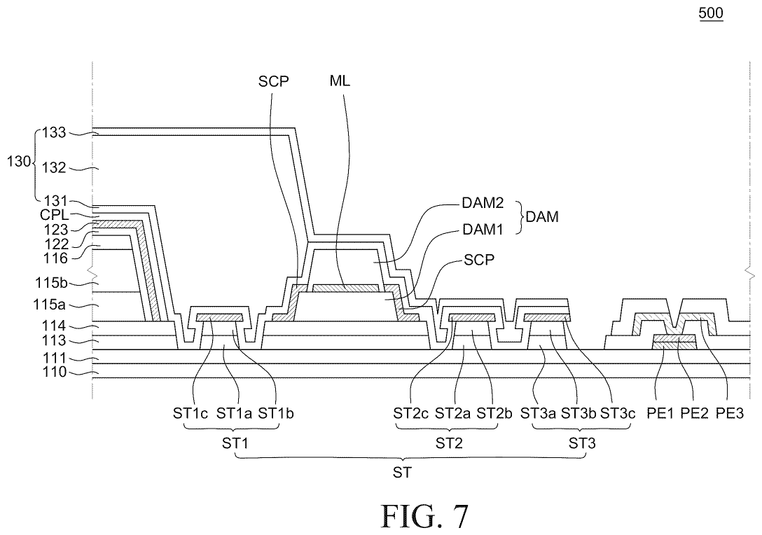

FIG. 7 is a cross-sectional view of a display device according to still another exemplary embodiment of the present disclosure. The difference between a display device 500 of FIG. 7 and the display device 200 of FIG. 4 is the presence or absence of a metal layer ML, but the other configurations are substantially the same, so that a redundant description will be omitted.

Referring to FIG. 7, a metal layer ML may be disposed between the first insulating layer DAM1 and the second insulating layer DAM2 of the dam DAM. Specifically, the metal layer ML may be disposed on the same layer as the connection electrode CE and may be formed of the same material as the connection electrode CE. For example, the metal layer ML may be formed of a material including titanium (Ti) or alloy thereof, but is not limited thereto. The metal layer ML may capture hydrogen so as not to degrade the characteristic of the transistor DT by the hydrogen of the encapsulation layer 130. Therefore, the metal layer ML may be formed of a material which may provide a stable bond with hydrogen, for example, a material including titanium (Ti) or alloy thereof, but is not limited thereto.

In the display device 500 according to still another exemplary embodiment of the present disclosure, the step relief pattern SCP which is formed by a material including titanium (Ti) or alloy thereof is disposed on a surface of the dam DAM to minimize or reduce the inflow of foreign particles through the seam and the crack of the encapsulation layer 130. Therefore, the reliability may be improved and the characteristic degradation of the driving transistor DT due to the diffusion of hydrogen of the encapsulation layer 130 may be reduced.

Specifically, in the display device 500 according to still another exemplary embodiment of the present disclosure, a metal layer ML including titanium (Ti) or alloy thereof is additionally disposed between the first insulating layer DAM1 and the second insulating layer DAM2 of the dam DAM. Therefore, the hydrogen of the encapsulation layer 130 is more effectively captured so that it may be further advantageous to reduce the characteristic degradation of the driving transistor DT due to the hydrogen diffusion.

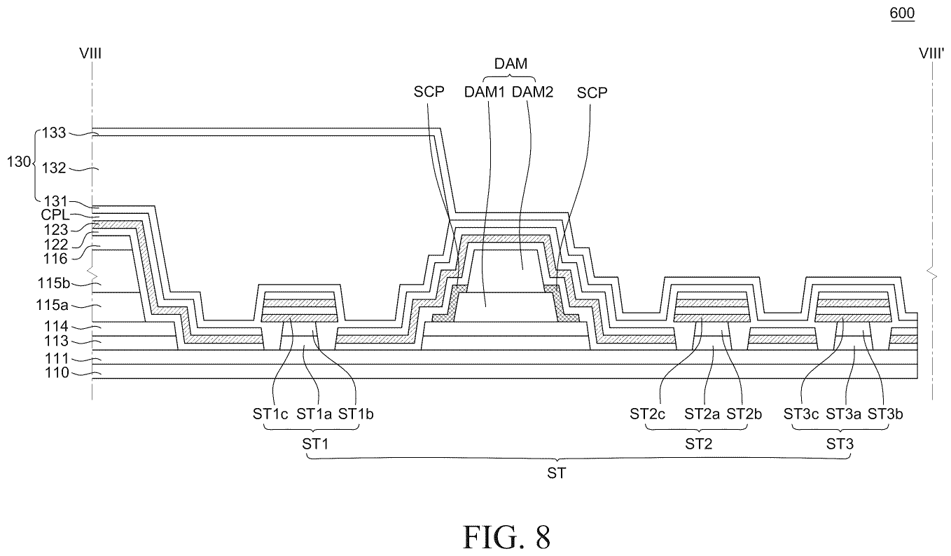

FIG. 8 is a cross-sectional view of a display device according to still another exemplary embodiment of the present disclosure. The difference between a display device 600 of FIG. 8 and the display device 100 of FIGS. 1 to 3 is placement of a light emitting layer 122, a cathode 123, and a capping layer CPL, but other components are substantially the same, so that a redundant description will be omitted. FIG. 8 is a cross-sectional view of a display device 600 for an area taken along line VIII-VIII′ illustrated in FIG. 1.

Referring to FIG. 8, the light emitting layer 122, the cathode 123, and the capping layer CPL may be disposed over the entire surface of the substrate 110.

In order to reduce a bezel area, after placing the light emitting layer 122, the cathode 123, and the capping layer CPL over the entire surface of the substrate 110, an outer area is cut by a scribing method to manufacture the display device 600 according to still another exemplary embodiment of the present disclosure. Therefore, an end of the light emitting layer 122, an end of the cathode 123, and an end of the capping layer CPL may be disposed on the same plane as an end of the substrate 110.

At this time, the light emitting layer 122, the cathode 123, and the capping layer CPL may be disconnected during the forming process due to an undercut shape of the plurality of structures ST. That is, the light emitting layer 122, the cathode 123, and the capping layer CPL may be partially disposed above the plurality of structures ST and may be disposed to be spaced apart from each other with respect to the plurality of structures ST. For example, the light emitting layer 122, the cathode 123, and the capping layer CPL may be disposed discontinuously between the plurality of structures ST and may be disposed to cover a part of a top surface of the buffer layer 111 disposed between the plurality of structures ST, but are not limited thereto. Therefore, the permeation of moisture and oxygen from the outside of the display device 600 into the active area AA through the light emitting layer 122 disposed in the non-active area NA may be suppressed.

In the display device 600 according to still another exemplary embodiment of the present disclosure, the step relief pattern SCP is disposed on a surface of the dam DAM to relieve a step between the first insulating layer DAM1 and the second insulating layer DAM2 which configures the dam DAM. Therefore, a seam and a crack may be suppressed from being generated in the first inorganic encapsulation layer 131 and the second inorganic encapsulation layer 133. Accordingly, the permeation of moisture through the seam and the crack of the first inorganic encapsulation layer 131 and the second inorganic encapsulation layer 133 may be suppressed.

That is, in the display device 600 according to still another exemplary embodiment of the present disclosure, the step relief pattern SCP is disposed on the surface of the dam DAM to minimize or reduce the inflow of foreign particles through the seam and the crack of the encapsulation layer 130. Therefore, the reliability may be improved and the display quality may be improved.

Further, in the display device 600 according to still another exemplary embodiment of the present disclosure, a step relief pattern SCP including titanium (Ti) or alloy thereof is disposed on the surface of the dam DAM to capture hydrogen generated in the encapsulation layer 130. Accordingly, the diffusion of the hydrogen of the encapsulation layer 130 to the driving transistor DT is suppressed to minimize or reduce degradation of the characteristic of the driving transistor DT due to the hydrogen.

Further, in the display device 600 according to still another exemplary embodiment of the present disclosure, a plurality of structures ST with an undercut shape are disposed at the inside and the outside of the dam DAM. For example, the plurality of structures ST may include a first structure ST1, a second structure ST2, and a third structure ST3. For example, an area of a bottom surface of the third layer ST1c of the first structure ST1 may be larger than an area of a top surface of the second layer ST1b of the first structure ST1. An area of a bottom surface of the third layer ST2c of the second structure ST2 may be larger than an area of a top surface of the second layer ST2b of the second structure ST2. An area of a bottom surface of the third layer ST3c of the third structure ST3 may be larger than an area of a top surface of the second layer ST3b of the third structure ST3. Further, the first inorganic encapsulation layer 131 and the second inorganic encapsulation layer 133 are disposed so as to enclose the surfaces of the plurality of structures ST with an undercut shape to elongate a path through which oxygen or moisture permeates. That is, the permeation of the oxygen or the moisture through the encapsulation layer 130 may be delayed.

Specifically, in the display device 600 according to still another exemplary embodiment of the present disclosure, even though the light emitting layer 122 is formed over the entire surface of the substrate 110, the light emitting layer is disposed to be spaced apart by the plurality of structures ST. Therefore, the permeation of moisture and oxygen from the outside into the active area AA through the light emitting layer 122 disposed in the non-active area NA may be suppressed.

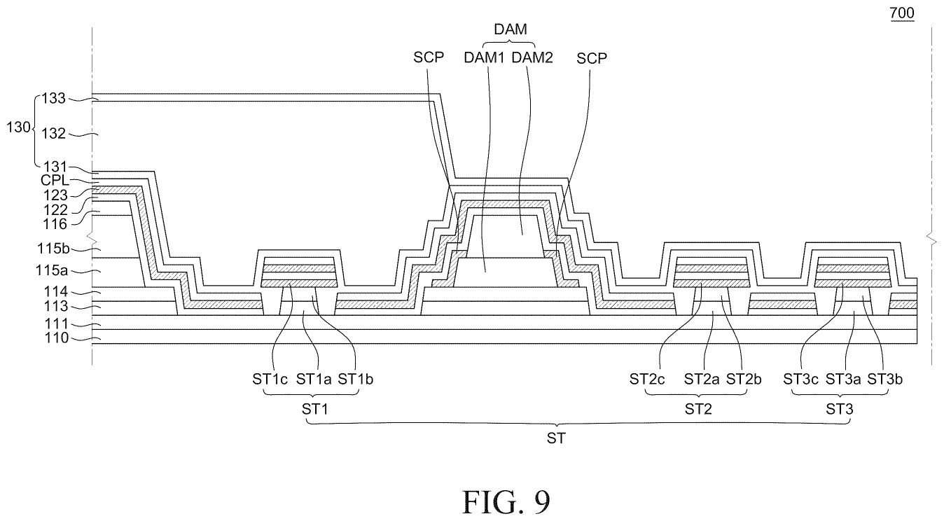

FIG. 9 is a cross-sectional view of a display device according to still another exemplary embodiment of the present disclosure. The difference between a display device 700 of FIG. 9 and the display device 600 of FIG. 8 is a step relief pattern SCP, but other components are substantially the same, so that a redundant description will be omitted.

Referring to FIG. 9, the step relief pattern SCP may be formed of the same material as the anode 121. Therefore, the step relief pattern SCP may be simultaneously formed in a deposition process of an anode 121 without adding a separate mask. Further, in order to suppress the degradation of the characteristic of the driving transistor DT due to the diffusion of the hydrogen of the encapsulation layer 130 to the driving transistor DT, the step relief pattern SCP may include a material including titanium (Ti) or alloy thereof, for example, molybdenum-titanium (MoTi), but is not limited thereto.

In the display device 700 according to still another exemplary embodiment of the present disclosure, the step relief pattern SCP which is formed by a material including titanium (Ti) or alloy thereof is disposed on a surface of the dam DAM to minimize or reduce the inflow of foreign particles through the seam and the crack of the encapsulation layer 130. Therefore, the reliability may be improved and the characteristic degradation of the driving transistor DT due to the diffusion of hydrogen of the encapsulation layer 130 may be reduced.

Specifically, in the display device 700 according to still another exemplary embodiment of the present disclosure, the step relief pattern SCP is simultaneously formed with the anode 121 without a separate mask-adding process so that a process efficiency may be improved and manufacturing cost may be reduced.

Further, in the display device 700 according to still another exemplary embodiment of the present disclosure, even though the light emitting layer 122 is formed over the entire surface of the substrate 110, the light emitting layer is disposed to be spaced apart by the plurality of structures ST. Therefore, the permeation of moisture and oxygen from the outside into the active area AA through the light emitting layer 122 disposed in the non-active area NA may be suppressed.

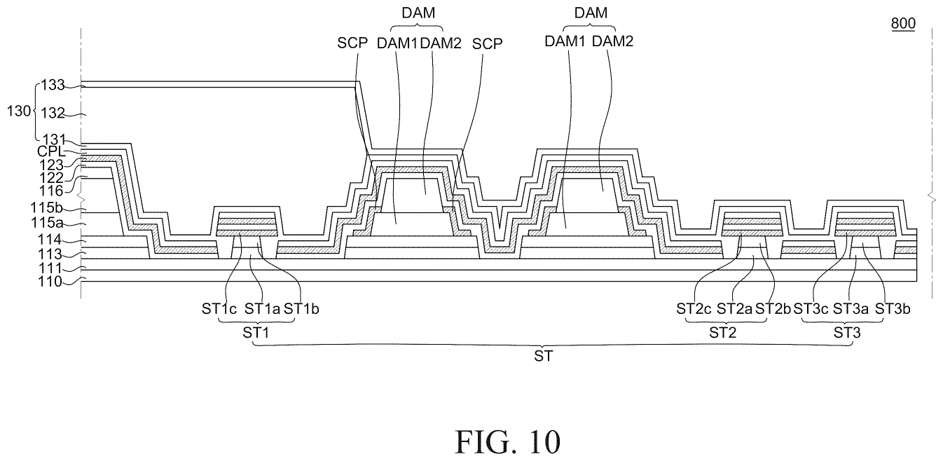

FIG. 10 is a cross-sectional view of a display device according to still another exemplary embodiment of the present disclosure. The difference between a display device 800 of FIG. 10 and the display device 700 of FIG. 9 is the number of dams DAM, but other components are substantially the same, so that a redundant description will be omitted.

Referring to FIG. 10, a plurality of dams DAM may be provided to minimize or reduce the overflow of the organic encapsulation layer 132. Even though in FIG. 10, two dams DAM are illustrated, the number of dams DAM is not limited thereto. For example, there or more dams DAM may be disposed.

Further, even though it is not illustrated in the drawing, a structure ST may be added between the plurality of dams DAM.

In the display device 800 according to still another exemplary embodiment of the present disclosure, the step relief pattern SCP which is formed by a material including titanium (Ti) or alloy thereof is disposed on a surface of the dam DAM to minimize or reduce the inflow of foreign particles through the seam and the crack of the encapsulation layer 130. Therefore, the reliability may be improved and the characteristic degradation of the driving transistor DT due to the diffusion of hydrogen of the encapsulation layer 130 may be reduced.

Specifically, in the display device 800 according to still another exemplary embodiment of the present disclosure, a plurality of dams DAM are disposed to more effectively suppress the overflow of the organic encapsulation layer 132.

Further, in the display device 800 according to still another exemplary embodiment of the present disclosure, even though the light emitting layer 122 is formed over the entire surface of the substrate 110, the light emitting layer is disposed to be spaced apart by the plurality of structures ST. Therefore, the permeation of moisture and oxygen from the outside into the active area AA through the light emitting layer 122 disposed in the non-active area NA may be suppressed.

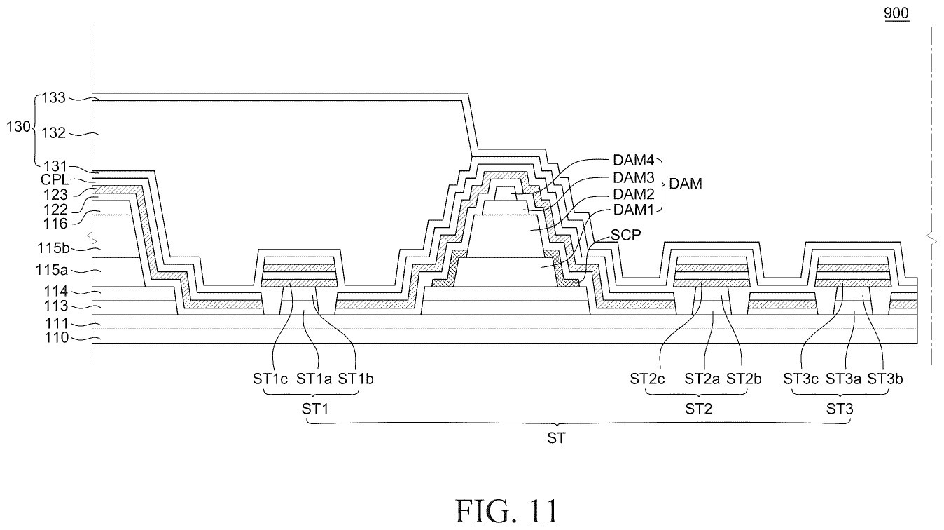

FIG. 11 is a cross-sectional view of a display device according to still another exemplary embodiment of the present disclosure. The difference between a display device 900 of FIG. 11 and the display device 700 of FIG. 9 is the presence or absence of a third insulating layer DAM3 and a fourth insulating layer DAM4, among configurations of the dam DAM, but other components are substantially the same, so that a redundant description will be omitted.

Referring to FIG. 11, the dam DAM may include a first insulating layer DAM1, a second insulating layer DAM2, a third insulating layer DAM3, and a fourth insulating layer DAM4.

The first insulating layer DAM1 may be formed on the same layer as the first planarization layer 115a and may be formed of the same material as the first planarization layer 115a, but is not limited thereto. At this time, a thickness of the first insulating layer DAM1 may be approximately 1.5 μm, but is not limited thereto.

The second insulating layer DAM2 may be disposed on the first insulating layer DAM1 and may be formed on the same layer as the second planarization layer 115b and may be formed of the same material as the second planarization layer 115b, but is not limited thereto. At this time, the second insulating layer DAM2 may be disposed to expose a part of a top surface of the first insulating layer DAM1. At this time, a thickness of the second insulating layer DAM2 may be approximately 1.5 μm, which is similar to the first insulating layer DAM1, but is not limited thereto.

The third insulating layer DAM3 may be disposed on the second insulating layer DAM2 and may be formed on the same layer as the bank 116 with the same material, but is not limited thereto. For example, the third insulating layer DAM3 may be formed of an insulating material. For example, the third insulating layer DAM3 may be formed of a polyimide resin, an acrylic resin, or a benzocyclobutene (BCB) resin, but is not limited thereto.

The fourth insulating layer DAM4 may be disposed on the third insulating layer DAM3 and may be formed on the same layer as the spacer with the same material, but is not limited thereto. For example, the fourth insulating layer DAM4 may be formed of an insulating material. For example, the fourth insulating layer DAM4 may be formed of a polyimide resin, an acrylic resin, or a benzocyclobutene (BCB) resin, but is not limited thereto.

Therefore, the third insulating layer DAM3 and the fourth insulating layer DAM4 may be thinner than the first insulating layer DAM1 and the second insulating layer DAM2, but are not limited thereto.

Further, the thicknesses of the third insulating layer DAM3 and the thickness of the fourth insulating layer DAM4 are smaller than the thickness of the first insulating layer DAM1 and the thickness of the second insulating layer DAM2. Therefore, a seam and a crack due to the step of the third insulating layer DAM3 and the fourth insulating layer DAM4 may not be generated in the first inorganic encapsulation layer 131 and the second inorganic encapsulation layer 133. Accordingly, a step relief pattern SCP which is in contact with side surfaces of the third insulating layer DAM3 and the fourth insulating layer DAM4 may not be necessary.

In the display device 900 according to still another exemplary embodiment of the present disclosure, the step relief pattern SCP which is formed by a material including titanium (Ti) or alloy thereof is disposed on a surface of the dam DAM to minimize or reduce the inflow of foreign particles through the seam and the crack of the encapsulation layer 130. Therefore, the reliability may be improved and the characteristic degradation of the driving transistor DT due to the diffusion of hydrogen of the encapsulation layer 130 may be reduced.

Specifically, in the display device 900 according to still another exemplary embodiment of the present disclosure, the dam DAM further includes not only the first insulating layer DAM1 and the second insulating layer DAM2, but also the third insulating layer DAM3 and the fourth insulating layer DAM4 to be configured higher. Therefore, it is more effective to suppress the overflow of the organic encapsulation layer 130.

Further, in the display device 900 according to still another exemplary embodiment of the present disclosure, even though the light emitting layer 122 is formed over the entire surface of the substrate 110, the light emitting layer is disposed to be spaced apart by the plurality of structures ST. Therefore, the permeation of moisture and oxygen from the outside into the active area AA through the light emitting layer 122 disposed in the non-active area NA may be suppressed.

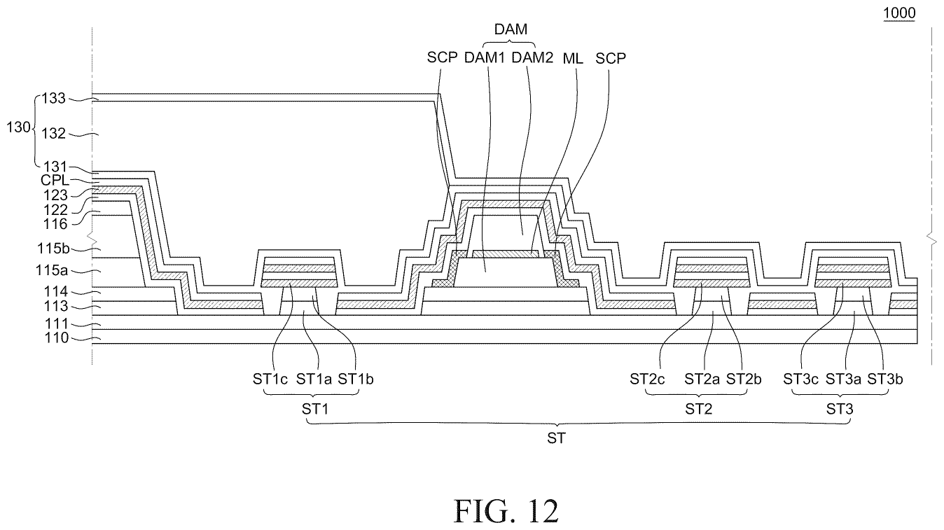

FIG. 12 is a cross-sectional view of a display device according to still another exemplary embodiment of the present disclosure. The only difference between a display device 1000 of FIG. 12 and the display device 700 of FIG. 9 is the presence or absence of a metal layer ML, but the other configurations are substantially the same, so that a redundant description will be omitted.

Referring to FIG. 12, a metal layer ML may be disposed between the first insulating layer DAM1 and the second insulating layer DAM2 of the dam DAM. Specifically, the metal layer ML is disposed on the same layer as the connection electrode CE and may be formed of the same material as the connection electrode CE. The metal layer ML may capture hydrogen so as not to degrade the characteristic of the transistor DT by the hydrogen of the encapsulation layer 130. Therefore, the metal layer ML may be formed of a material which may form stable bond with hydrogen, for example, a material including titanium (Ti) or alloy thereof, but is not limited thereto.

In the display device 1000 according to still another exemplary embodiment of the present disclosure, the step relief pattern SCP which is formed by a material including titanium (Ti) or alloy thereof is disposed on a surface of the dam DAM to minimize or reduce the inflow of foreign particles through the seam and the crack of the encapsulation layer 130. Therefore, the reliability may be improved and the characteristic degradation of the driving transistor DT due to the diffusion of hydrogen of the encapsulation layer 130 may be reduced.

Specifically, in the display device 1000 according to still another exemplary embodiment of the present disclosure, a metal layer ML including titanium (Ti) or alloy thereof is additionally disposed between the first insulating layer DAM1 and the second insulating layer DAM2 of the dam DAM. Therefore, the hydrogen of the encapsulation layer 130 is more effectively captured so that it may be further advantageous to reduce the characteristic degradation of the driving transistor DT due to the hydrogen diffusion.

Further, in the display device 1000 according to still another exemplary embodiment of the present disclosure, even though the light emitting layer 122 is formed over the entire surface of the substrate 110, the light emitting layer is disposed to be spaced apart by the plurality of structures ST. Therefore, the permeation of moisture and oxygen from the outside into the active area AA through the light emitting layer 122 disposed in the non-active area NA may be suppressed.

The exemplary embodiments of the present disclosure can also be described as follows:

According to an aspect of the present disclosure, there is provided a display device. The display device includes a substrate including an active area and a non-active area which extends from the active area, a light emitting diode which is disposed on the substrate and includes an anode, a light emitting layer, and a cathode, a dam which is disposed in the non-active area of the substrate and a step relief pattern which is disposed in a part of a surface of the dam. The dam includes a first insulating layer and a second insulating layer on the first insulating layer, and the step relief pattern is disposed so as to enclose a side surface of the first insulating layer and a lower portion of a side surface of the second insulating layer.

The second insulating layer may be disposed so as to expose a part of a top surface of the first insulating layer.

The step relief pattern may be in contact with the part of the top surface of the first insulating layer exposed by the second insulating layer.

An end of the step relief pattern may be disposed on the same plane as an end of the first insulating layer.

The step relief pattern may be formed of the same material as the anode.

The step relief pattern may be formed of a conductive material which is different from the anode.

The step relief pattern may be formed of a material including titanium (Ti).

The display device may further include a bank and a spacer disposed in the active area of the substrate. The dam may further include a third insulating layer which is disposed on the second insulating layer and is formed of the same material as the bank and a fourth insulating layer which is disposed on the third insulating layer and is formed of the same material as the spacer.

The display device may further include a metal layer disposed between the first insulating layer and the second insulating layer.

The display device may further include a connection electrode which is disposed below the light emitting diode to be electrically connected to the anode. The metal layer may be disposed on the same layer as the connection electrode with the same material.

The metal layer may be formed of a material including titanium (Ti).

The display device may further include a capping layer disposed on the light emitting diode. An end of the light emitting layer, an end of the cathode, and an end of the capping layer may be disposed on the same plane as an end of the substrate.

The display device may further include a plurality of structures disposed at an inside and an outside of the dam. The plurality of structures may be formed with an undercut shape.

Each of the plurality of structures may include an upper layer and a lower layer, and an area of a bottom surface of the upper layer is larger than an area of a top surface of the lower layer.

The upper layer and the lower layer are formed of different materials.

The upper layer is formed a conductive material, and the lower layer is formed of an insulating material.

Each of the plurality of structures may include a first layer, a second layer, and a third layer, and an area of a bottom surface of the third layer is larger than an area of a top surface of the second layer.

The third layer is formed a conductive material, and the first layer and the second layer are formed of insulating materials.

The third layer is formed of the same material as that of the anode, and the first layer and the second layer are formed of insulating materials.

The display device may further include a capping layer disposed on the light emitting diode. The light emitting layer, the cathode, and the capping layer may be disposed to be spaced part from each other through the plurality of structures.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including an active area and a non-active area that extends from the active area;
a light emitting diode on the substrate, the light emitting diode including an anode, a light emitting layer, and a cathode;
a dam in the non-active area of the substrate; and
a step relief pattern in a part of a surface of the dam,
wherein the dam includes a first insulating layer and a second insulating layer on the first insulating layer, and the step relief pattern encloses a side surface of the first insulating layer and a lower portion of a side surface of the second insulating layer.

2. The display device according to claim 1, wherein the second insulating layer exposes a part of a top surface of the first insulating layer.

3. The display device according to claim 2, wherein the step relief pattern is in contact with the part of the top surface of the first insulating layer exposed by the second insulating layer.

4. The display device according to claim 1, wherein an end of the step relief pattern is on a same plane as an end of the first insulating layer.

5. The display device according to claim 1, wherein the step relief pattern comprises a same material as the anode.

6. The display device according to claim 1, wherein the step relief pattern comprises a different conductive material than the anode.

7. The display device according to claim 1, wherein the step relief pattern comprises titanium.

8. The display device according to claim 1, further comprising:
a bank and a spacer in the active area of the substrate,
wherein the dam further includes:
a third insulating layer on the second insulating layer, the third insulating layer comprising a same material as the bank, and
a fourth insulating layer on the third insulating layer, the fourth insulating layer comprising a same material as the spacer.

9. The display device according to claim 1, further comprising:
a metal layer between the first insulating layer and the second insulating layer.

10. The display device according to claim 9, further comprising:
a connection electrode below the light emitting diode and electrically connected to the anode,
wherein the metal layer is on a same layer as the connection electrode and comprises a same material as the connection electrode.

11. The display device according to claim 9, wherein the metal layer comprises titanium.

12. The display device according to claim 1, further comprising:
a capping layer on the light emitting diode,
wherein an end of the light emitting layer, an end of the cathode, and an end of the capping layer are on a same plane as an end of the substrate.

13. The display device according to claim 1, further comprising:
a plurality of structures at an inside and an outside of the dam,
wherein the plurality of structures comprise an undercut shape.

14. The display device according to claim 13,
wherein each of the plurality of structures includes an upper layer and a lower layer, and
wherein an area of a bottom surface of the upper layer is larger than an area of a top surface of the lower layer.

15. The display device according to claim 14,
wherein the upper layer and the lower layer comprise different materials.

16. The display device according to claim 15,
wherein the upper layer comprises a conductive material, and the lower layer comprises an insulating material.

17. The display device according to claim 13,
wherein each of the plurality of structures includes a first layer, a second layer, and a third layer, and
wherein an area of a bottom surface of the third layer is larger than an area of a top surface of the second layer.

18. The display device according to claim 17,
wherein the third layer comprises a conductive material, and the first layer and the second layer comprise insulating materials.

19. The display device according to claim 17,
wherein the third layer comprises a same material as the anode, and
wherein the first layer and the second layer comprise insulating materials.

20. The display device according to claim 13, further comprising:
a capping layer on the light emitting diode,
wherein the light emitting layer, the cathode, and the capping layer are spaced apart from each other through the plurality of structures.
